(19) United States
(12) Patent Application Publication
(10) Pub. No.: US 2007/0085620 A1
(43) Pub. Date: Apr. 19, 2007

(54) Semiconductor integrated circuit device

(75) Inventors: Hiroaki Ohkubo, Kanagawa (JP); Yasutaka Nakashiba, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC ELECTRONICS CORPORATION, Kawasaki (JP)

(21) Appl. No.: 11/544,661

(22) Filed: Oct. 10, 2006

(30) Foreign Application Priority Data
Oct. 14, 2005 (JP) 2005-300150

(51) Int. Cl. H03B 5/12

(52) U.S. Cl. 331/177 V

(57) ABSTRACT

A voltage-controlled oscillator operates stably over a narrow variation range of a control voltage, including a variable capacitance circuit 12 controllable by voltage, an inductor circuit 11 having inductors, a negative resistance circuit 13, and a capacitance control circuit 14 that outputs a correction voltage. An oscillator circuit is constituted by the variable capacitance circuit 12, the inductor circuit 11, and the negative resistance circuit 13 connected in parallel. The capacitance control circuit 14 controls to correct the capacitance of the variable capacitance circuit 12 with the correction voltage outputted in response to a temperature fluctuation and/or power supply voltage fluctuation in the oscillator circuit.

### FIELD OF THE INVENTION

The present invention relates to a semiconductor integrated circuit device, and particularly to a semiconductor integrated circuit device including a voltage controllable oscillator circuit.

### BACKGROUND OF THE INVENTION

As a local oscillator in a phase locked loop (PLL) circuit used for the purposes of frequency multiplication or phase synchronization, a ring oscillator was conventionally used. A ring oscillator is constituted by an odd-number of CMOS (Complementary Metal Oxide Semiconductor) inverters connected in a ring, and it can be formed in a MOS integrated circuit. Such a ring oscillator has high jitter in an oscillation signal since it includes many active elements.

Meanwhile, a voltage-controlled oscillator utilizing the resonance of a parallel LC tank circuit (abbreviated as LC-VCO) has been used as a local oscillator in recent years. Compared with the ring oscillator, the LC-VCO has the following advantages. First, the LC-VCO produces less noise than the ring oscillator does. This is due to the fact that, since the oscillator circuit of the LC-VCO utilizes the resonance of a parallel LC tank circuit, it has fewer transistors, which can cause noise. Second, it is easier to obtain a high oscillation frequency with the LC-VCO than with the ring oscillator which utilizes the delay of logic gates, because the oscillator circuit of the LC-VCO utilizes the resonance of a parallel LC tank circuit. Third, the oscillation frequency varies less versus a control voltage in the LC-VCO. This allows for a lower tuning sensitivity, and the fluctuation of the oscillation frequency caused by the variation of the control voltage is small, resulting in low noise. These features allow the LC-VCO to be suitable for use in high-speed optical telecommunications, mobile phones, wireless LANs and the like.

An LC-VCO that can suppress the deterioration of phase noise characteristics is disclosed in Patent Document 1. FIG. 7 is a circuit diagram of the LC-VCO disclosed in Patent Document 1. In FIG. 7, the LC-VCO comprises an inductor circuit composed of inductors 104a and 104b, n pieces (n is two or more; an example where n=3 is shown in FIG. 7) of variable capacitance circuits having variable capacitance elements 105a and 105b (106a and 106b, and 107a and 107b), a negative resistance circuit constituted by oscillation transistors 103a and 103b, and reference voltage generation means 114 for generating a reference voltage from a power supply voltage.

One ends of the inductors 104a and 104b are connected to a power source terminal 100 in common. The other end of the inductor 104a is connected to each end of the variable capacitance elements 105a, 106a, and 107a via DC cut capacitors 108a, 109a, and 110a respectively, and is further connected to the drain of the oscillation transistor 103a and the gate of the oscillation transistor 103b. The other end of the inductor 104b is connected to each end of the variable capacitance elements 105b, 106b, and 107b via DC cut capacitors 108b, 109b, and 110b, respectively, and is further connected to the drain of the oscillation transistor 103b and the gate of the oscillation transistor 103a. Sources of the oscillation transistors 103a and 103b are connected in common, and further is grounded via a current source 101.

Further, the variable capacitance elements 105a and 105b are connected (i.e., share) a common node via high-frequency blocking resistors 111a and 111b, respectively, and a reference voltage Vref generated by the reference voltage generation means 114 is supplied to the common node. The variable capacitance elements 106a and 106b share a common node via high-frequency blocking resistors 112a and 112b, respectively, and a reference voltage Vref-Vd generated by the reference voltage generation means 114 is supplied to the common node. The variable capacitance elements 107a and 107b share a common node via high-frequency blocking resistors 113a and 113b, respectively, and a reference voltage Vref-2Vd generated by the reference voltage generation means 114 is supplied to the common node. Further, the other ends of the variable capacitance elements 105a and 105b; 106a and 106b; and 107a and 107b are connected into a common node, respectively, and each common node is connected to a frequency control terminal 102.

In the LC-VCO structured as above, the oscillation frequency is controlled according to a control voltage applied to the frequency control terminal 102. Since predetermined reference voltages supplied to one of the terminals of the variable capacitance elements in at least two variable capacitance circuits out of the variable capacitance elements in the n pieces of the variable capacitance circuits are different (for instance Vref, Vref-Vd, and Vref-2Vd), it is controlled so that the capacitance of the n pieces of the variable capacitance circuits varies over a wide range of the control voltage. As a result, frequency sensitivity to the control voltage becomes low, to provide better phase noise characteristics.

[Patent Document 1]

Japanese Patent Kokai Publication No. JP-P2004-147310A (FIG. 1)

### SUMMARY OF THE DISCLOSURE

Meanwhile, in recent years, the LC-VCO used for mobile phones operates in high frequency bands from several GHz to several tens of GHz. Also, it is expected to operate stably even when the power supply voltage used drops to around 1V. Under these conditions, the range in which the control voltage varies becomes narrower, and the capacitance of the variable capacitance circuits needs to vary according to the narrow range in which the control voltage varies. However, since the capacitance of the variable capacitance circuits is controlled to vary over a wide range of the control voltage in the LC-VCO disclosed in Patent Document 1, it is difficult for it to operate stably if the range in which the control voltage varies is narrow.

On the other hand, in case where when it is simply controlled so that the capacitance of a single variable capacitance circuit varies in order to deal with the narrow range in which the control voltage varies, the VCO might not be able to follow variations in oscillation frequency caused by the fluctuations of the temperature and the power supply voltage, and it might not fulfill the function as a voltage controllable oscillator circuit. In other words, the circuit characteristics of the oscillator circuit are changed by temperature fluctuations and power supply voltage fluctuations, and over a narrow range of the control voltage, it is difficult to control the capacitance so that the circuit oscillates at a predetermined oscillation frequency.

According to a first aspect of the present invention, there is provided a semiconductor integrated circuit device, which comprises: a variable capacitance circuit controllable by voltage, an inductor circuit having inductors; a negative resistance circuit, a correction voltage generating circuit that outputs a correction voltage, and a control terminal to which a voltage for controlling an oscillation frequency is supplied. Further, an oscillator circuit is constituted by the variable capacitance circuit, the inductor circuit, and the negative resistance circuit connected in parallel, and the variable capacitance circuit is structured so that the capacitance is varied according to a voltage of the control terminal and the correction voltage.

In a second aspect, the variable capacitance circuit may be a first capacitance circuit composed of a first variable capacitance element and a second variable capacitance element connected in series, and a voltage at a connection node between the first variable capacitance element and the second variable capacitance element is controlled by an output voltage of the correction voltage generating circuit and a voltage of the control terminal.

In a third aspect, the variable capacitance circuit may be constituted by parallel-connecting a first capacitance circuit composed of a first variable capacitance element and a second variable capacitance element connected in series and a second capacitance circuit composed of a third variable capacitance element and a fourth variable capacitance element connected in series, a connection node between the first variable capacitance element and the second variable capacitance element is connected to an output end of the correction voltage generating circuit, and a connection node between the third variable capacitance element and the fourth variable capacitance element is connected to the control terminal.

In a fourth aspect, the correction voltage generating circuit may output the correction voltage in response to a temperature fluctuation and/or a power supply fluctuation in the oscillator circuit.

In a fifth aspect, the variable capacitance circuit may be constituted by parallel-connecting a first capacitance circuit composed of a first variable capacitance element and a second variable capacitance element connected in series, a second capacitance circuit composed of a third variable capacitance element and a fourth variable capacitance element connected in series, and a third capacitance circuit composed of a fifth variable capacitance element and a sixth variable capacitance element connected in series; the correction voltage generating circuit includes a temperature fluctuation monitor circuit that outputs a voltage corrected according to a temperature fluctuation in the oscillator circuit and a voltage fluctuation monitor circuit that outputs a voltage corrected according to a fluctuation in power supply in the oscillator circuit, the connection node between the first variable capacitance element and the second variable capacitance element being connected to the control terminal, the connection node between the third variable capacitance element and the fourth variable capacitance element being connected to an output end of the temperature fluctuation monitor circuit, and the connection node between the fifth variable capacitance element and the sixth variable capacitance element being connected to an output end of the voltage fluctuation monitor circuit.

In a sixth aspect, the variable capacitance element in the semiconductor integrated circuit device may be a MOS transistor whose gate capacitance is variable.

In a seventh aspect, a temperature fluctuation monitor circuit may include one diode or a plurality of cascade-connected diodes, and outputs the correction voltage according to a forward voltage drop of the diode.

In an eighth aspect, a temperature fluctuation monitor circuit may be constituted by two cascade-connected resistance elements having different temperature coefficients from each other, and a voltage at the connection node between the two resistance elements becomes the correction voltage.

In a ninth aspect, the voltage fluctuation monitor circuit may divide a power supply voltage of the oscillator circuit to output the correction voltage.

The meritorious effects of the present invention are summarized as follows.

According to the present invention, an oscillator circuit can operate stably over a narrow variation range of a control voltage since it is controlled so that the capacitance of a variable capacitance circuit is corrected by a correction voltage outputted in response to a temperature fluctuation and/or power supply voltage fluctuation in the oscillator circuit.

### BRIEF DESCRIPTIONS OF THE DRAWINGS

FIG. 1 is a circuit diagram illustrating the structure of a voltage-controlled oscillator relating to an embodiment of the present invention.

FIG. 2 is a circuit diagram illustrating the structure of a voltage-controlled oscillator relating to a first embodiment of the present invention.

FIG. 3 is a circuit diagram illustrating the structure of a voltage-controlled oscillator relating to a second embodiment of the present invention.

FIG. 4 is a circuit diagram illustrating the structure of a voltage-controlled oscillator relating to a third embodiment of the present invention.

FIG. 5 is a circuit diagram illustrating the structure of a voltage-controlled oscillator relating to a fourth embodiment of the present invention.

FIGS. 6A and 6B are drawings showing a structure example of an variable capacitance element and how the capacitance changes.

FIG. 7 is a circuit diagram of a conventional LC-VCO.

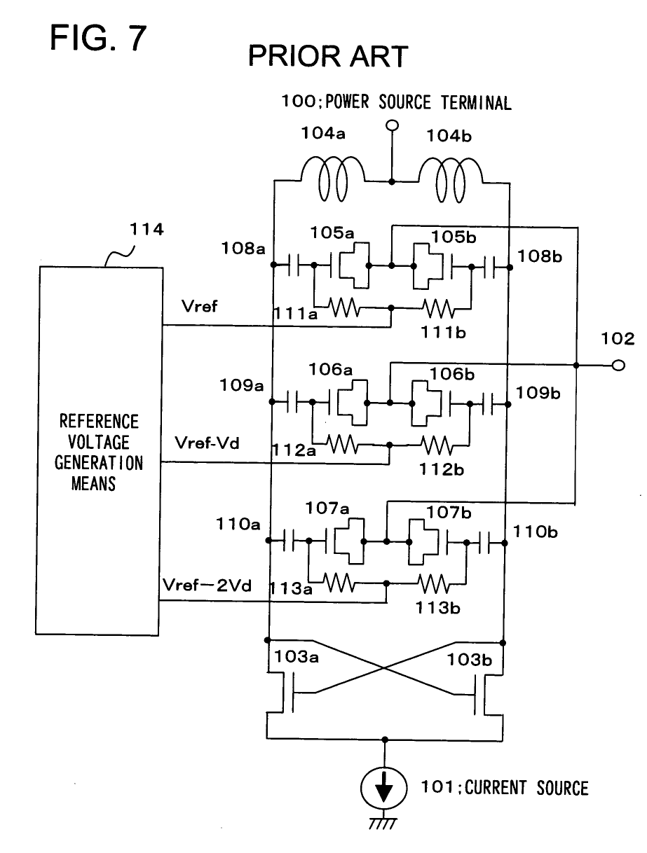

### PREFERRED EMBODIMENTS OF THE INVENTION

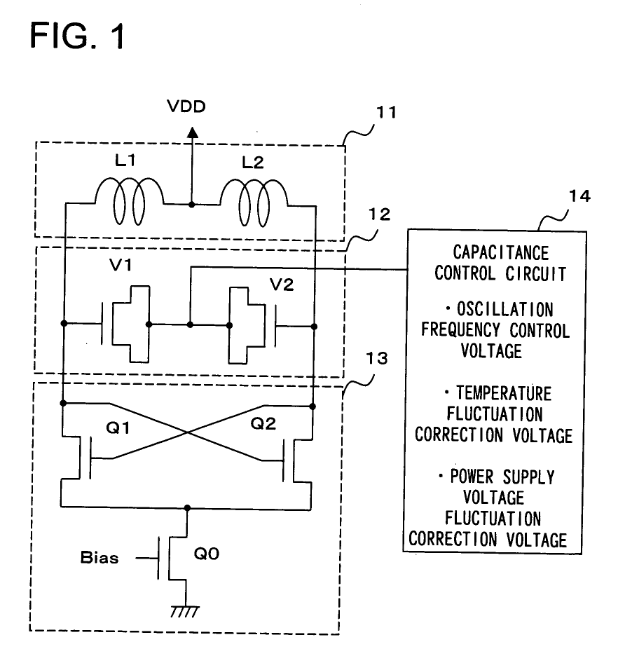

FIG. 1 is a circuit diagram illustrating the structure of a voltage-controlled oscillator relating to an embodiment of the present invention. In FIG. 1, the voltage-controlled oscillator comprises an inductor circuit 11, a variable capacitance circuit 12, a negative resistance circuit 13, and a capacitance control circuit 14. The inductor circuit 11 is constituted by a pair of series-connected inductors L1 and L2, and the inductors L1 and L2 share a common end, which is connected to a power supply VDD. Spiral inductors formed on the chip are used as the inductors L1 and L2. Further, the variable capacitance circuit 12 is constituted by a pair of cascade-connected variable capacitance elements V1 and V2, and the variable capacitance elements V1 and V2 share a common end (node), which is connected to the capacitance control circuit 14. For instance, varactors—MOS transistors in which the capacitance between the common-connected source/drain and the gate is varied by the voltage between the source/drain and the gate—are used as the variable capacitance elements V1 and V2. Note, the “negative resistance” denotes a resistance with a negative temperature coefficient.

The negative resistance circuit 13 is constituted by NchMOS transistors Q0, Q1, and Q2. The drain of the NchMOS transistor Q1 and the gate of the NchMOS transistor Q2 are connected in common to the other end of the inductor L1 and to the other end of the variable capacitance element V1. The drain of the NchMOS transistor Q2 and the gate of the NchMOS transistor Q1 are connected in common to the other end of the inductor L2 and to the other end of the variable capacitance element V2. Further, sources of the NchMOS transistors Q1 and Q2 are connected to a common node, which is grounded via the NchMOS transistor Q0. A predetermined bias voltage Bias is applied to the gate of the NchMOS transistor Q0, a current source.

The capacitance control circuit 14 supplies a control voltage for controlling the oscillation frequency of the voltage-controlled oscillator to one ends (common node) of the variable capacitance elements V1 and V2. At this time, a control voltage corrected so that it corresponds to a temperature fluctuation and/or a power supply voltage fluctuation in the voltage-controlled oscillator is supplied to one ends of the variable capacitance elements V1 and V2. More concretely, an amount of voltage corresponding to the amount of the temperature fluctuation and/or power supply voltage fluctuation is weight added to the control voltage supplied to the one ends of the variable capacitance elements V1 and V2. Or as described later in embodiments, a plurality of variable capacitance element pairs are provided, and a voltage corresponding to the amount of the temperature fluctuation or power supply voltage fluctuation is supplied to each pair of the variable capacitance elements.

The voltage-controlled oscillator structured as above is formed on a chip. This voltage-controlled oscillator oscillates at a resonance frequency determined by the inductance of the inductor circuit 11 and the capacitance of the variable capacitance circuit 12 when the sum of the combined resistance of the inductor circuit 11 and the variable capacitance circuit 12, and the resistance of the negative resistance circuit 13 becomes negative. At this time, the capacitance of the variable capacitance circuit 12 is varied by having the capacitance control circuit 14 supply a voltage for controlling the oscillation frequency to one ends of the variable capacitance elements V1 and V2. The resonance frequency reacts to this and changes as well. In sum, the capacitance control circuit 14 outputs the control voltage for controlling the oscillation frequency. In response to temperature fluctuations and/or the power supply voltage fluctuations of the voltage-controlled oscillator, this control voltage is corrected so that the change in the resonance frequency is reduced. Therefore, even when there is a temperature fluctuation and/or power supply voltage fluctuation, the resonance frequency is corrected and the oscillator circuit operates stably over a narrow variation range of the control voltage.

Embodiments will be described in detail below, particularly focusing on the concrete structures of the capacitance control circuit 14.

Embodiment 1

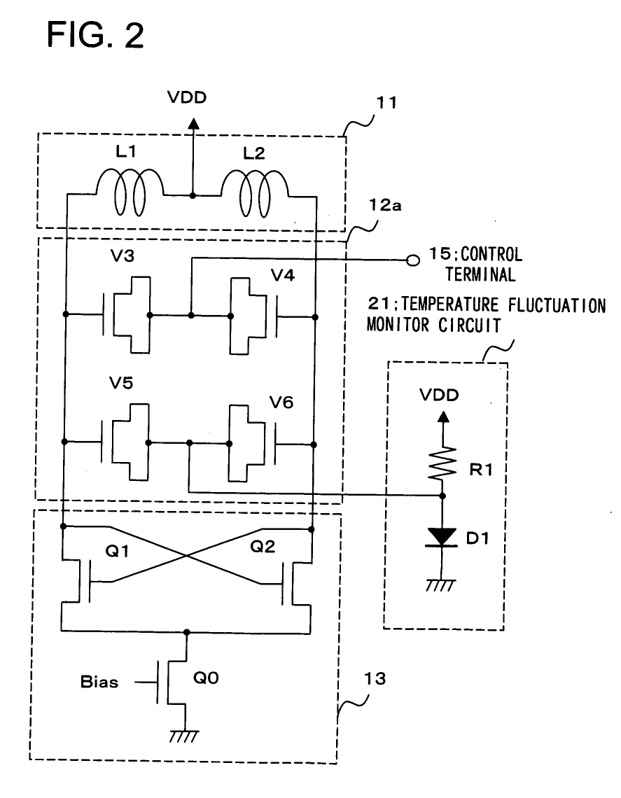

In a first embodiment, an example where the capacitance of the variable capacitance circuit is controlled by a correction voltage outputted in response to temperature fluctuations is described. FIG. 2 is a circuit diagram illustrating the structure of a voltage-controlled oscillator relating to the first embodiment of the present invention. In FIG. 2, the same symbols as the ones in FIG. 1 represent the same things, thus explanations of them will be omitted. A variable capacitance circuit 12a is constituted by cascade-connected variable capacitance elements V3 and V4 and variable capacitance elements V5 and V6, also cascade-connected. The variable capacitance elements V3 and V4 share a common end (node), which is connected to a control terminal 15. The variable capacitance elements V5 and V6 share a common end (node), which is connected to the anode of a diode D1 in a temperature fluctuation monitor circuit 21. The other ends of the variable capacitance elements V3 and V5 are connected in common to the other end of the inductor L1. The other ends of the variable capacitance elements V4 and V6 are connected in common to the other end of the inductor L2.

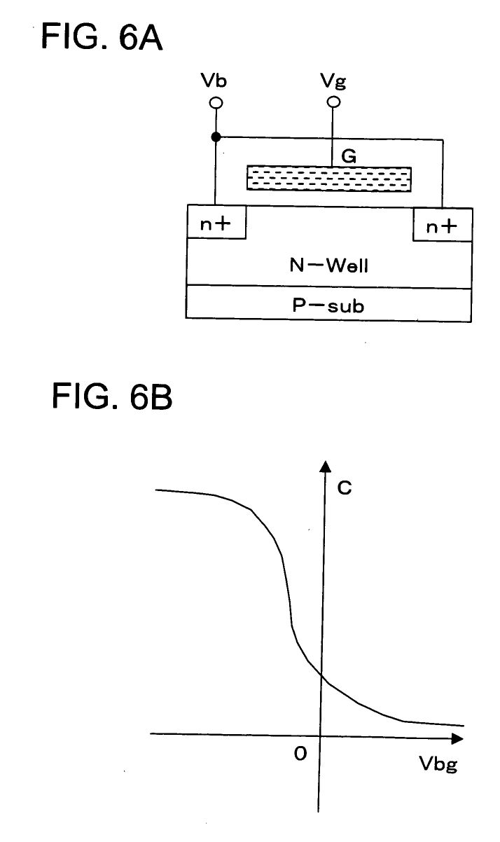

The temperature fluctuation monitor circuit 21 comprises a resistance element R1 having one end connected to the power supply VDD and the other end connected to the anode of the diode D1, and the diode D1 having its anode connected to the end of the resistance element R1 and its cathode grounded. Further, a voltage equal to the forward voltage drop of the diode D1 is supplied to one ends (common node) of the variable capacitance elements V5 and V6. Since the forward voltage of the diode D1 generally has a negative temperature coefficient (the anode voltage of D1 increases as the temperature of D1 rises, and thus), each potential difference between both ends of the variable capacitance elements V5 and V6, respectively, increases when the temperature of the diode D1 is elevated. As a result, the capacitance of the variable capacitance elements V5 and V6 changes. For instance, let's assume that the variable capacitance elements V5 and V6 have a structure shown in FIG. 6A. In the variable capacitance element shown in FIG. 6A, a voltage Vb is applied to two n+ diffusion layer regions formed in an N-well on a P-type substrate (P-sub), and a voltage Vg is applied to a gate electrode G provided for the N-well between the two n+ diffusion layer regions through an insulating film. At this time, as shown in FIG. 6B, a capacitance C of the variable capacitance element decreases as a voltage Vbg (=Vb−Vg) increases.

The voltage-controlled oscillator structured as above oscillates at a resonance frequency between the inductance of the inductor circuit 11 and the combined capacitance of the variable capacitance circuit 12a. At this time, it is controlled so that the capacitance of the variable capacitance circuit 12a is varied by the control voltage of the control terminal 15 and the anode voltage of the diode D1. The control voltage of the control terminal 15 controls the oscillation frequency of the voltage-controlled oscillator by controlling the capacitance of the variable capacitance elements V3 and V4. Meanwhile, the temperature fluctuation monitor circuit 21 controls to correct changes in the oscillation frequency of the voltage-controlled oscillator caused by temperature fluctuations by controlling the capacitance of the variable capacitance elements V5 and V6. Therefore, even when there is a temperature fluctuation, the resonance frequency is corrected and the oscillator circuit operates stably over a narrow variation range of the control voltage.

In the above description, only one diode is used in the temperature fluctuation monitor, however, two or more diodes may be cascade-connected, and the voltage at the connection point with the other end of the resistance element R1 may be supplied to one ends (common node) of the variable capacitance elements V5 and V6 if the power supply VDD is high.

Embodiment 2

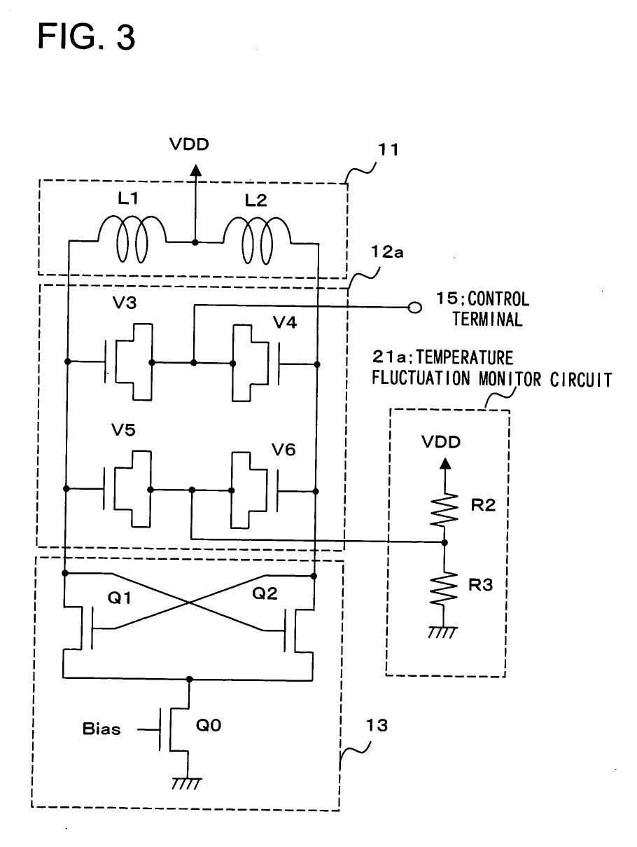

In a second embodiment, another example where the capacitance of the variable capacitance circuit is controlled by a correction voltage outputted in response to temperature fluctuations is described. FIG. 3 is a circuit diagram illustrating the structure of a voltage-controlled oscillator relating to the second embodiment of the present invention. In FIG. 3, the same symbols as the ones in FIG. 2 represent the same things, thus explanations of them will be omitted. The variable capacitance elements V5 and V6 share a common end (node), which is connected to one end of a resistance element R3 in a temperature fluctuation monitor circuit 21a.

The temperature fluctuation monitor circuit 21a comprises a resistance element R2 having one end connected to the power supply VDD and the other end connected to one end of the resistance element R3, and the resistance element R3 having one end connected to the other end of the resistance element R2 and the other end grounded. Further, a voltage at an end (common node) of the resistance element R3 is supplied to one ends (common node) of the variable capacitance elements V5 and V6. The resistance element R2 is made of a material such as titanium (Ti) for instance and its resistance value has a positive temperature coefficient (+0.3%/° C. in the case of Ti). Further, the resistance element R3 is made of a material such as vanadium oxide (Vox) for instance, and its resistance value has a negative temperature coefficient (−1.5%/° C.).

The voltage-controlled oscillator structured as above operates similarly to the one in the first embodiment, and even when there is a temperature fluctuation, the resonance frequency is corrected and the oscillator circuit operates stably over a narrow variation range of the control voltage.

Embodiment 3

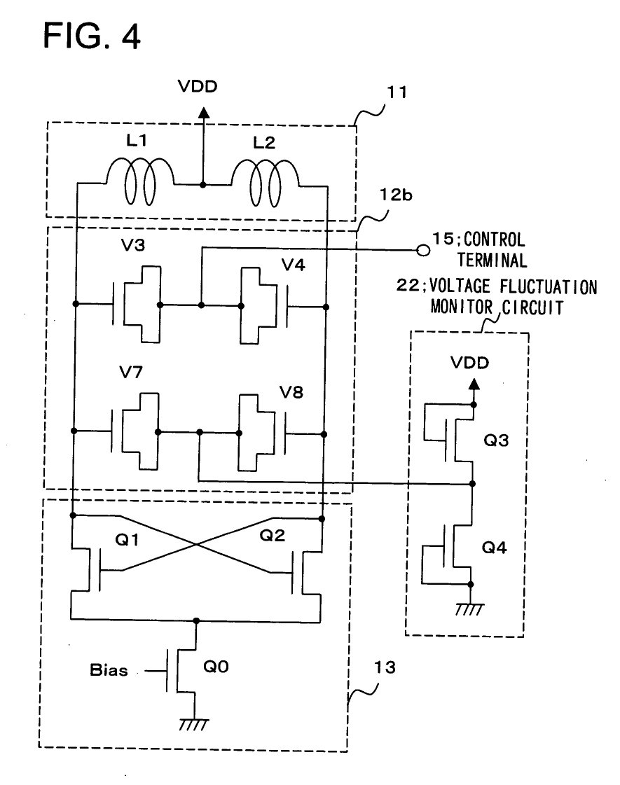

In a third embodiment, an example where the capacitance of the variable capacitance circuit is controlled by a correction voltage outputted particularly in response to power supply voltage fluctuations is described. FIG. 4 is a circuit diagram illustrating the structure of a voltage-controlled oscillator relating to the third embodiment of the present invention. In FIG. 4, the same symbols as the ones in FIG. 2 represent the same things, thus explanations of them will be omitted. A variable capacitance circuit 12b is constituted by the cascade-connected variable capacitance elements V3 and V4 and variable capacitance elements V7 and V8, also cascade-connected. The variable capacitance elements V7 and V8 share a common end (node), which is connected to the drain of an NchMOS transistor Q4 in a voltage fluctuation monitor circuit 22. The other ends of the variable capacitance elements V3 and V7 are connected in common to the other end of the inductor L1. The other ends of the variable capacitance elements V4 and V8 are connected in common to the other end of the inductor L2.

The voltage fluctuation monitor circuit 22 comprises a PchMOS transistor Q3 having its source and gate connected to the power supply VDD and its drain connected to the NchMOS transistor Q4, and the NchMOS transistor Q4 having its source and gate grounded and its drain connected to the PchMOS transistor Q3. The PchMOS transistor Q3 and the NchMOS transistor Q4 function as resistance elements, and a divided voltage of the power supply VDD occurs at the drain of the NchMOS transistor Q4. The divided voltage is supplied to one ends (common node) of the variable capacitance elements V7 and V8.

The voltage-controlled oscillator structured as above oscillates at a resonance frequency between the inductance of the inductor circuit 11 and the combined capacitance of the variable capacitance circuit 12b. At this time, it is controlled so that the capacitance of the variable capacitance circuit 12b is varied by the control voltage of the control terminal 15 and a drain voltage of the NchMOS transistor Q4. The control voltage of the control terminal 15 controls the oscillation frequency of the voltage-controlled oscillator by controlling the capacitance of the variable capacitance elements V3 and V4. Meanwhile, the voltage fluctuation monitor circuit 22 controls to correct changes in the oscillation frequency of the voltage-controlled oscillator caused by power supply voltage fluctuations by controlling the capacitance of the variable capacitance elements V7 and V8 with the divided power supply voltage. Therefore, even when there is a power supply voltage fluctuation, the resonance frequency is corrected and the oscillator circuit operates stably over a narrow variation range of the control voltage.

In the above description, the voltage fluctuation monitor circuit 22 is constituted by cascade-connected transistors, however, it may be constituted by cascade-connected resistance elements as is the temperature fluctuation monitor circuit 21a in FIG. 3. In other words, the temperature fluctuation monitor circuit 21a shown in FIG. 3 can function as the voltage fluctuation monitor circuit as well.

Embodiment 4

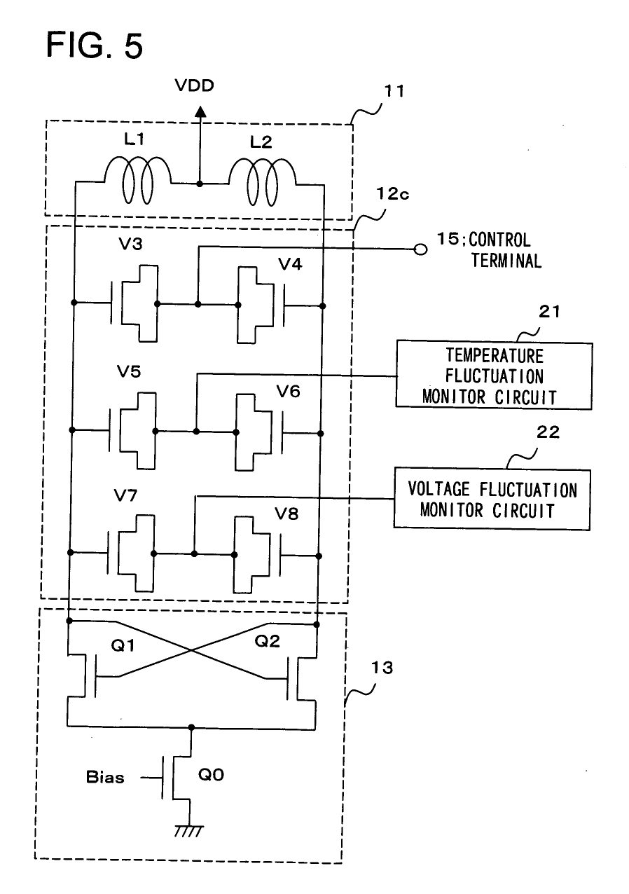

In a fourth embodiment, an example where the capacitance of the variable capacitance circuit is controlled by a correction voltage outputted in response to the fluctuations of the temperature and the power supply voltage is described. FIG. 5 is a circuit diagram illustrating the structure of a voltage-controlled oscillator relating to the fourth embodiment of the present invention. In FIG. 5, the same symbols as the ones in FIG. 4 represent the same things, thus explanations of them will be omitted. A variable capacitance circuit 12c is constituted by the cascade-connected variable capacitance elements V3 and V4, the cascade-connected variable capacitance elements V5 and V6, and the cascade-connected variable capacitance elements V7 and V8. The variable capacitance elements V5 and V6 share a common end, which is connected to the temperature fluctuation monitor circuit 21. Further, the variable capacitance elements V7 and V8 share a common end, which is connected to the voltage fluctuation monitor circuit 22. The other ends of the variable capacitance elements V3, V5, and V7 are connected in common to the other end of the inductor L1. The other ends of the variable capacitance elements V4, V6, and V8 are connected in common to the other end of the inductor L2.

The voltage-controlled oscillator structured as above oscillates at a resonance frequency between the inductance of the inductor circuit 11 and the combined capacitance of the variable capacitance circuit 12c. At this time, it is controlled so that the capacitance of the variable capacitance circuit 12c is varied by the control voltage of the control terminal 15, the output voltage of the temperature fluctuation monitor circuit 21, and the output voltage of the voltage fluctuation monitor circuit 22. The control voltage of the control terminal 15 controls the oscillation frequency of the voltage-controlled oscillator by controlling the capacitance of the variable capacitance elements V3 and V4. Further, as described in the first embodiment, the temperature fluctuation monitor circuit 21 controls to correct changes in the oscillation frequency of the voltage-controlled oscillator caused by temperature fluctuations by controlling the capacitance of the variable capacitance elements V5 and V6. The voltage fluctuation monitor circuit 22 controls to correct changes in the oscillation frequency of the voltage-controlled oscillator caused by power supply voltage fluctuations by controlling the capacitance of the variable capacitance elements V7 and V8 as described in the third embodiment. Therefore, even when there is the fluctuations in the temperature and the power supply voltage, the resonance frequency is corrected and the oscillator circuit operates stably over a narrow variation range of the control voltage.

Note that variable capacitance elements utilizing accumulation MOS (FIG. 6A) where capacitance is formed between the gate and the drain/source are used as the variable capacitance elements in the embodiments described above. However, the present invention is not limited to this structure, and variable capacitance elements utilizing inversion MOS where capacitance is formed between the gate and the drain/source may be used for some or all of the variable capacitance elements as necessary. In sum, it is preferable that appropriate variable capacitance element pairs be selected so that the fluctuations in the resonance frequency caused by temperature fluctuations or power supply voltage fluctuations are reduced as much as possible. Further, it is also preferable that the sizes of the transistors in the variable capacitance element pairs be appropriately set so that the fluctuations in the resonance frequency caused by temperature fluctuations and/or power supply voltage fluctuations are reduced as much as possible.

It should be noted that other objects, features and aspects of the present invention will become apparent in the entire disclosure and that modifications may be done without departing the gist and scope of the present invention as disclosed herein and claimed as appended herewith.

Also it should be noted that any combination of the disclosed and/or claimed elements, matters and/or items may fall under the modifications aforementioned.

What is claimed is:

1. A semiconductor integrated circuit device comprising:
a variable capacitance circuit controllable by voltage;
an inductor circuit having inductors;
a negative resistance circuit;
a correction voltage generating circuit that outputs a correction voltage; and
a control terminal to which a voltage for controlling an oscillation frequency is supplied; wherein
an oscillator circuit is constituted by said variable capacitance circuit, said inductor circuit, and said negative resistance circuit connected in parallel, and said variable capacitance circuit is structured so that the capacitance is varied according to a voltage of said control terminal and said correction voltage.

2. The semiconductor integrated circuit device as defined in claim 1, wherein said variable capacitance circuit is a first capacitance circuit composed of a first variable capacitance element and a second variable capacitance element connected in series, and a voltage at a connection node between said first variable capacitance element and said second variable capacitance element is controlled by an output voltage of said correction voltage generating circuit and a voltage of said control terminal.

3. The semiconductor integrated circuit device as defined in claim 1, wherein said variable capacitance circuit is constituted by parallel-connecting a first capacitance circuit composed of a first variable capacitance element and a second variable capacitance element connected in series and a second capacitance circuit composed of a third variable capacitance element and a fourth variable capacitance element connected in series, a connection node between said first variable capacitance element and said second variable capacitance element is connected to an output end of said correction voltage generating circuit, and a connection node between said third variable capacitance element and said fourth variable capacitance element is connected to said control terminal.

4. The semiconductor integrated circuit device as defined in claim 1, wherein said correction voltage generating circuit outputs said correction voltage in response to a temperature fluctuation and/or a power supply fluctuation in said oscillator circuit.

5. The semiconductor integrated circuit device as defined in claim 1, wherein said variable capacitance circuit is constituted by parallel-connecting a first capacitance circuit composed of a first variable capacitance element and a second variable capacitance element connected in series, a second capacitance circuit composed of a third variable capacitance element and a fourth variable capacitance element connected in series, and a third capacitance circuit composed of a fifth variable capacitance element and a sixth variable capacitance element connected in series;
said correction voltage generating circuit includes a temperature fluctuation monitor circuit that outputs a voltage corrected according to a temperature fluctuation in said oscillator circuit and a voltage fluctuation monitor circuit that outputs a voltage corrected according to a fluctuation in power supply in said oscillator circuit,
the connection node between said first variable capacitance element and said second variable capacitance element being connected to said control terminal,
the connection node between said third variable capacitance element and said fourth variable capacitance element being connected to an output end of said temperature fluctuation monitor circuit, and
the connection node between said fifth variable capacitance element and said sixth variable capacitance element being connected to an output end of said voltage fluctuation monitor circuit.

6. A semiconductor integrated circuit device, wherein said variable capacitance element in the semiconductor integrated circuit device as defined in claim 2 is a MOS transistor whose gate capacitance is variable.

7. The semiconductor integrated circuit device as defined in claim 5, wherein a temperature fluctuation monitor circuit includes one diode or a plurality of cascade-connected diodes, and outputs said correction voltage according to a forward voltage drop of the diode.

8. The semiconductor integrated circuit device as defined in claim 5, wherein a temperature fluctuation monitor circuit is constituted by two cascade-connected resistance elements having different temperature coefficients from each other, and a voltage at the connection node between the two resistance elements becomes said correction voltage.

9. The semiconductor integrated circuit device as defined in claim 5, wherein said voltage fluctuation monitor circuit divides a power supply voltage of said oscillator circuit and outputs said correction voltage.
